(19) United States
(12) Patent Application Publication
(10) Pub. No.: US 2016/0284622 A1
(43) Pub. Date: Sep. 29, 2016

(54) COOLING STRUCTURE AND DEVICE

(71) Applicant: NEC Corporation, Tokyo (JP)

(72) Inventor: Tomoyuki MITSUI, Tokyo (JP)

(73) Assignee: NEC Corporation

(21) Appl. No.: 15/072,552

(22) Filed: Mar. 17, 2016

(30) Foreign Application Priority Data
Mar. 23, 2015 (JP) 2015-059699

(51) Int. Cl. H01L 23/367; H01L 23/40; F28F 3/04; F28F 3/02

(52) U.S. Cl. CPC H01L 23/3672; F28F 3/02; H01L 23/40; F28F 3/04

(57) ABSTRACT

An object of the present invention is to constantly maintain the degree of contact between a heat generating element that generates high temperature and a heat dissipater. To achieve the object, a cooling structure 130 according to the present invention includes a heat dissipater 140 which is disposed in such a way as to thermally couple to a plurality of heat generating elements 120 and dissipates heat generated by the plurality of heat generating elements 120, and a protruding portion 143 which is positioned at a surface of the heat dissipater 140 that faces the heat generating elements 120 and reduces the distance to a first heat generating element 121 that generates the highest temperature among the heat generating elements 120.

This application is based upon and claims the benefit of priority from Japanese Patent Application No. 2015-059699, filed on Mar. 23, 2015, the disclosure of which is incorporated herein in its entirety by reference.

### TECHNICAL FIELD

The present invention relates to a cooling structure and a device.

### BACKGROUND ART

In recent years, electronic devices (devices) such as personal computers have been enhanced. As electronic devices are enhanced, the amounts of heat generated by heat generating elements, such as CPUs, CPU's peripheral integrated circuits, and power source circuits, which are installed in personal computers are increasing. “CPU” is an abbreviation of “Central Processing Unit”. There is therefore a demand for a technique for efficiently dissipating heat generated by heat generating elements into a heat dissipater such as a heat sink.

In a device in which heat generated by multiple heat generating elements is dissipated by a single heat dissipater, the degrees of contact between the heat generating elements and the heat dissipater vary from one heat generating element to another. This is because the heat generating elements are at different heights due to factors such as warpage of the substrate, a tilt of the substrate, variations in the height among the heat generating elements, and mounting errors which can occur in mounting of the heat generating elements on the substrate.

Such different degrees of contact of heat generating elements with a heat dissipater can cause unevenness in the effect of dissipating heat generated by the heat generating elements. If the degree of contact of a high-temperature heat generating element with the heat dissipater is low compared with the degree of contact of a low-temperature heat generating element with the heat dissipater, the effect of dissipating heat generated by the high-temperature heat generating element is decreased. A technique is generally known that reduces such unevenness in the heat dissipation effect by interposing a thermally-conductive sheet between heat generating elements and a heat dissipater to closely contact the heat generating elements with the heat dissipater. However, it is preferable that the degrees of contact of heat generating elements with a heat dissipater be equal or the degree of contact between a high-temperature heat generating element and a heat dissipater be higher than the degree of contact between a low-temperature heat generating element and the heat dissipater.

To minimize variations in the degree of contact of heat generating elements with a heat dissipater as described above, Japanese Patent Laid-open Publication No. 11-121666 (PTL1), for example, discloses a technique relating to a cooling device for a multi-chip module. The technique in PTL1 includes a plurality of electronic components P and provides a recess in a surface of a heat dissipater 1 that faces the thickest electronic component P among the plurality of electronic components P of a multi-chip module, as illustrated in FIG. 1 of PTL1. This absorbs differences in the degree of contact of the heat generating elements with the heat dissipater to reduce unevenness of the heat dissipating effect.

Japanese Patent Publication No. 294405 (PLT2) discloses a technique relating to a cooling structure and an electromagnetic shielding structure for a semiconductor device. In the technique in PLT2, a projection 16 is provided on the underside of a heat sink 5 as illustrated in FIG. 4 of PLT2. The projection 16 is positioned in a location on the underside of the heat sink 5 that faces a semiconductor device 1 embedded in a substrate. This absorbs a height difference between a surface-mount package 7 which protrudes from the surface of the substrate and the semiconductor device 1 embedded in the substrate.

### SUMMARY

However, while the techniques described in PLT1 and PLT2 absorb differences in the degree of contact of heat generating elements with a heat dissipater to reduce unevenness of the heat dissipating effect, it is unclear whether the techniques make the degree of contact between a high-temperature heat generating element and a heat dissipater higher than the degree of contact between a low-temperature heat generating element and the heat dissipater. The techniques in PLT1 and PLT2 can possibly make the degree of contact between a low-temperature heat generating element and a heat dissipater higher than the degree of contact between a high-temperature heat generating element and the heat dissipater. The techniques in PTL1 and PLT2 thus do not actively enhance the degree of contact between a high-temperature heat generating element and a heat dissipater and therefore cannot preferentially dissipate heat generated by the high-temperature heat generating element, as can be seen from the foregoing.

In light of these circumstances, an object of the present invention is to provide a cooling structure and a device that are capable of actively enhancing the degree of contact between a high-temperature heat generating element and a heat dissipater.

To achieve the object, a cooling structure according to the present invention includes a heat dissipater which is disposed in such a way as to thermally couple to a plurality of heat generating elements and dissipates heat generated by the plurality of heat generating elements, and a protruding portion which is positioned at a surface of the heat dissipater that faces the heat generating elements, wherein the protruding portion reduces the distance between the heat dissipater and the heat generating element.

To achieve the object, a heat dissipater according to the present invention includes a protruding portion which is disposed at a surface of the heat dissipater that faces heat generating elements, wherein the protruding portion reduces the distance between the heat dissipater and the heat generating element.

To achieve the object, a device according to the present invention includes the cooling structure and the plurality of heat generating elements.

### Advantageous Effect of the Invention

According to the present invention, the degree of contact between a high-temperature heat generating element and a heat dissipater can actively be enhanced.

### BRIEF DESCRIPTION OF THE DRAWINGS

FIG. 1 is a side view illustrating a configuration of a cooling structure according to one exemplary embodiment (a first exemplary embodiment) of the present invention and an electronic device (a device) equipped with the cooling structure;

FIG. 2 is an exploded perspective view illustrating a configuration of a cooling structure according to an alternative exemplary embodiment (a second exemplary embodiment) of the present invention and an electronic device (a device) equipped with the cooling structure;

FIG. 3 is a side view illustrating a configuration of the cooling structure according to the alternative exemplary embodiment (the second exemplary embodiment) of the present invention and the electronic device (the device) equipped with the cooling structure and illustrating a first state of the cooling structure and the electronic device;

FIG. 4 is a side view illustrating a configuration of the cooling structure according to the alternative exemplary embodiment (the second exemplary embodiment) of the present invention and the electronic device (the device) equipped with the cooling structure and illustrating a second state of the cooling structure and the electronic device;

FIG. 5 is a plan view illustrating a configuration of a cooling structure according to another alternative exemplary embodiment (a third exemplary embodiment) of the present invention and an electronic device (a device) equipped with the cooling structure; and

FIG. 6 is a side view illustrating the cooling structure and the electronic device viewed from direction A in FIG. 5.

### EXEMPLARY EMBODIMENTS

Exemplary embodiments of the present invention will be described below with reference to the drawings.

### First Exemplary Embodiment

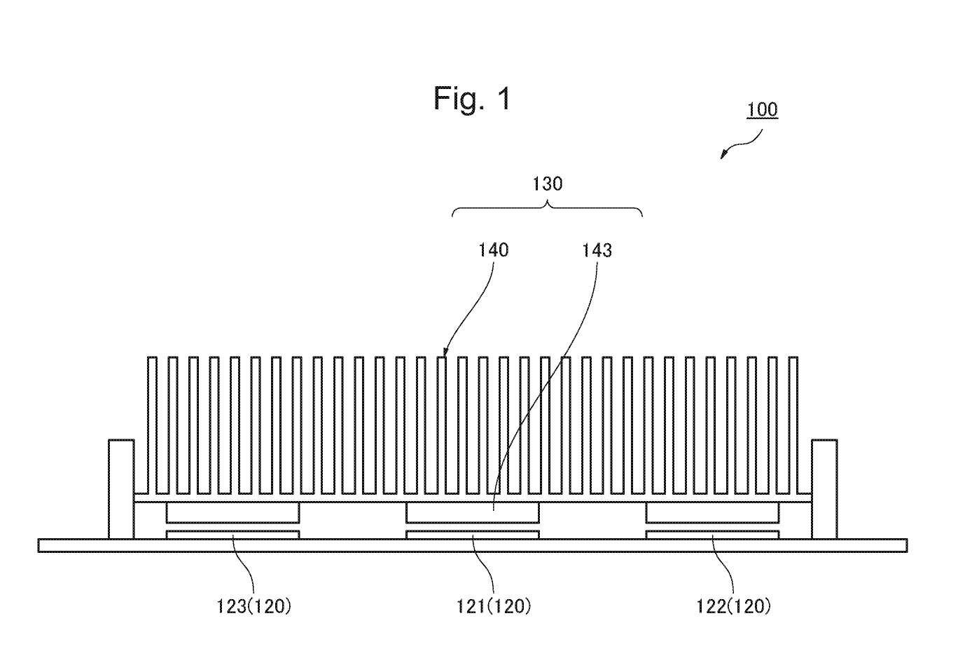

One exemplary embodiment (a first exemplary embodiment) of the present invention will be described with reference to FIG. 1. FIG. 1 is a side view illustrating a configuration of a cooling structure 130 according to this exemplary embodiment (the first exemplary embodiment) and an electronic device (a device) 100 equipped with the cooling structure 130. The cooling structure 130 includes a heat dissipater 140, a protruding portion 143, and a holding mechanism 160.

The heat dissipater 140 is disposed in such a way as to thermally couple to a plurality of heat generating elements 120 and dissipates heat generated by the plurality of heat generating elements 120. The protruding portion 143 is positioned at a surface of the heat dissipater 140 that faces the heat generating elements 120 so that the distance to a first heat generating element 121 that generates the highest temperature is reduced.

In the cooling structure 130 according to this exemplary embodiment, the distance between the first heat generating element 121 that generates high temperature and the heat dissipater 140 is reduced to preferentially bring the heat dissipater 140 into contact with the heat generating element that generates high temperature. Consequently, the cooling structure 130 of this exemplary embodiment is capable of actively enhancing the degree of contact between the first heat generating element 121 that generates high temperature and the heat dissipater 140.

Similarly, in the electronic device 100 according to this exemplary embodiment, the distance between the first heat generating element 121 that generates high temperature and the heat dissipater 140 is reduced to preferentially bring the heat dissipater 140 into contact with the heat generating element that generates high temperature. Consequently, the electronic device of this exemplary embodiment is capable of actively enhancing the degree of contact between the first heat generating element 121 that generates high temperature and the heat dissipater 140.

### Second Exemplary Embodiment

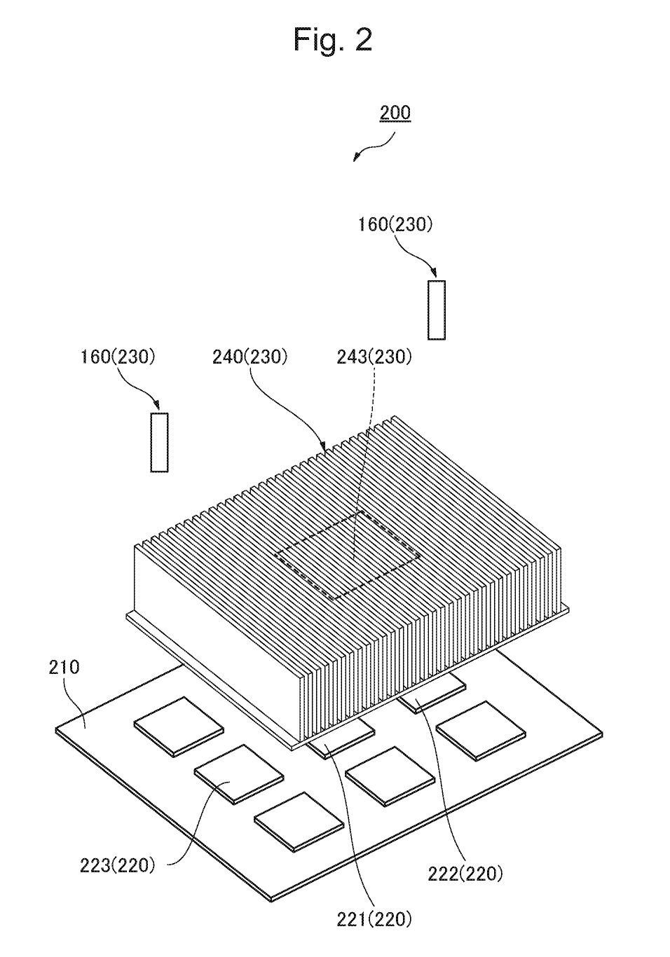

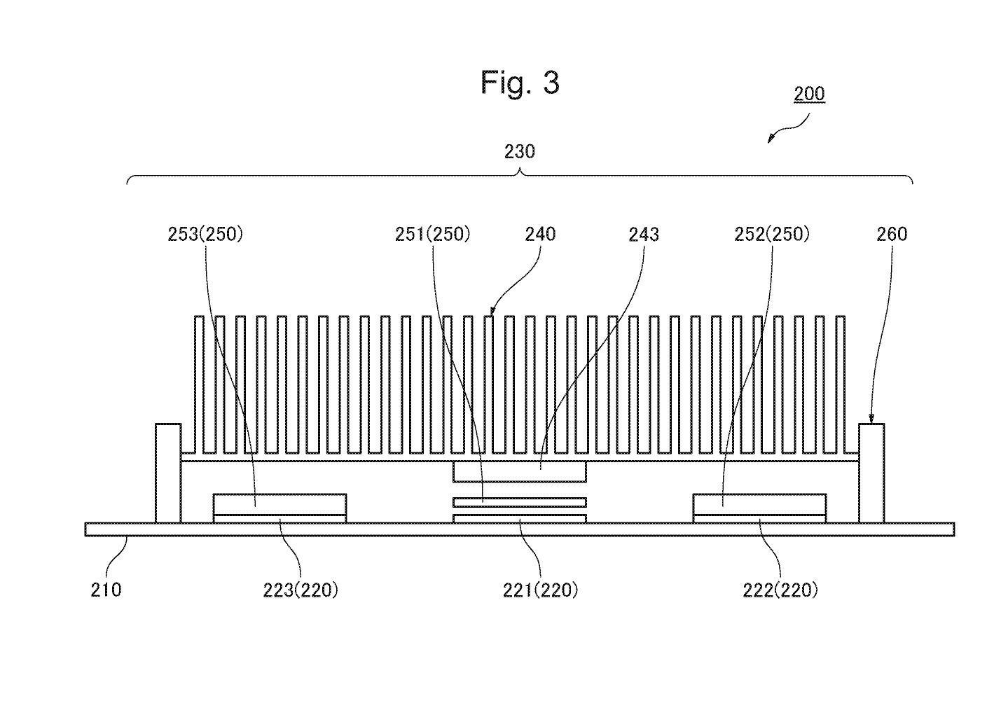

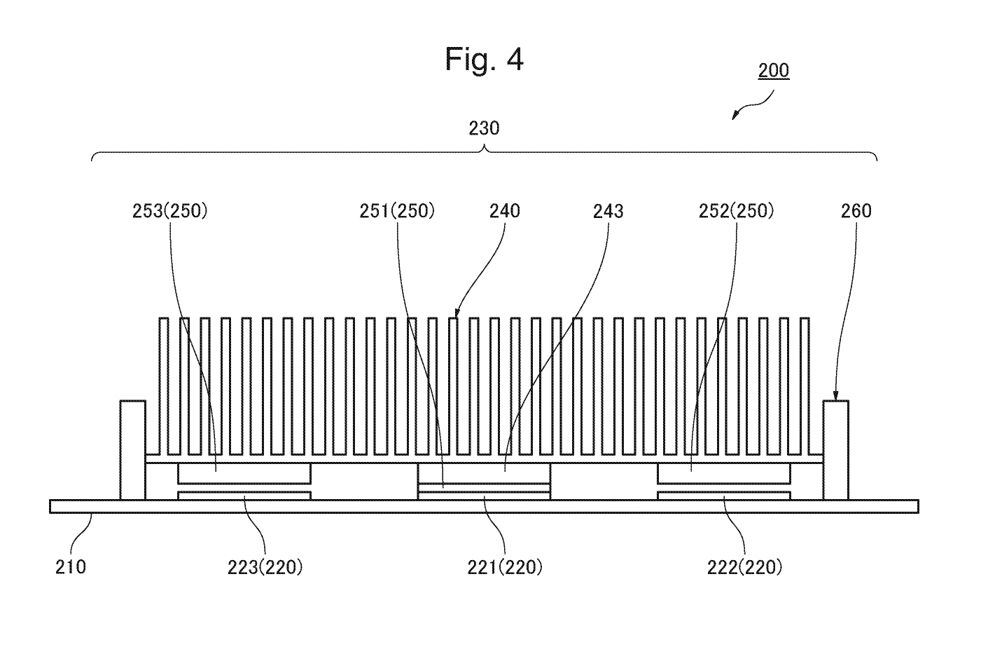

An alternative exemplary embodiment (a second exemplary embodiment) of the present invention will be described with reference to FIGS. 2 to 4. FIG. 2 is an exploded perspective view illustrating a configuration of a cooling structure 230 according to this exemplary embodiment (the second exemplary embodiment) and an electronic device (a device) 200 equipped with the cooling structure 230. FIGS. 3 and 4 are cross-sectional view illustrating the configuration of the cooling structure 230 according to this exemplary embodiment (the second exemplary embodiment) and the electronic device (the device) 200 equipped with the cooling structure 230 and illustrating first and second states, respectively, of the cooling structure 230 and the electronic device 200. The first state is a state before a heat dissipater 240 is pressed against heat generating elements 220. The second sate is a state after the heat dissipater 240 is pressed against the heat generating elements 220.

The electronic device 200 includes a substrate 210, heat generating elements 220 and the cooling structure 230. The substrate 210 is well known from the prior art and therefore will be only briefly described with no detailed description; the substrate 210 is made of a material such as phenol resin or epoxy resin in the shape of a plate. The plurality of heat generating elements 220 are disposed on a surface of the plate-shaped substrate 210.

The heat generating elements 220 are integrated circuit elements such as CPU, IC, LSI, or MPU, for example, which are well known from the prior art and therefore detailed descriptions thereof will be omitted. The heat generating elements 220 generate heat when they are in operation. In order to dissipate heat generated by the heat generating elements 220, the cooling structure 230 is thermally coupled to the heat generating elements 220. “IC” is an abbreviation of “Integrated Circuit”. “LSI” is an abbreviation of “Large Scale Integration”. “CPU” is an abbreviation of “Central Processing Unit”. “MPU” is an abbreviation of “Micro Processing Unit”.

The cooling structure 230 includes the heat dissipater 240, heat conductive members 250, and a first holding mechanism 260. The cooling structure 230 dissipates heat generated by the heat generating elements 220. The heat dissipater 240 is used for dissipating heat generated by the heat generating elements 220 and is made of metal that has high thermal conductivity, such as aluminum, iron or copper. The heat dissipating dissipater 240 may be a heat sink, for example.

An example of the heat dissipater 240 includes a plate-fin heat sink. The plate-fin heat sink is made up of a base and a plurality of plate fins. The plurality of plate fins are provided to stand on the base. In the heat sink, the plurality of plate fins extend along the path of airflow from an air blower, not depicted. Accordingly, air sent to the heat sink by the air blower can pass between the plate fins to cool the entire heat sink. This enhances the effect of the heat sink to dissipate heat generated by the heat generating elements 220.

In this exemplary embodiment, a protruding portion 243 is provided in a location on a surface of the heat dissipater 240 that faces a first heat generating element 221 that generates the highest temperature among the plurality of heat generating elements 220. The protruding portion 243 is formed in such a way as to protrude from the surface that faces the first heat generating element 221 toward the first heat generating element 221. Accordingly, when the heat dissipater 240 is pressed against the heat generating elements 220, the protruding portion 243 of the heat dissipater 240 can be brought into contact with the first heat generating element 221 before the other heat generating elements. In other words, the heat dissipater 240 can be brought into contact with the first heat generating element 221 preferentially.

Thermally-conductive members 250 are interposed between the heat generating elements 220 and the heat dissipater 240. The thermally-conductive members 250 are in close contact with the heat generating elements 220 and the heat dissipater 240 under the pressure of the heat dissipater 240. The thermally-conductive members 250 transfer heat generated by the heat generating elements 220 into the heat dissipater 240. The plurality of thermally conductive members 250 are made of materials such as thermally-conductive resin.

In this exemplary embodiment, the plurality of thermally-conductive members 250 are made of different materials that depend on the distances between the heat dissipater 240 and the heat generating elements 220. Heat dissipation performance can be represented by thermal resistance. A lower thermal resistance represents a better heat dissipation performance whereas a higher thermal resistance represents a poor heat dissipation performance. Thermal resistance can be calculated as: distance between heat generating element 220 and heat dissipater 240/(thermal conductivity x area of contact between heat generating element 220 and heat dissipater 240). Therefore, in order to lower thermal resistance, the distance between the heat generating element 220 and the heat dissipater 240 is reduced, or a material that easily transfers heat is used, or the area of contact between the heat generating element 220 and the heat dissipater 240 is increased.

In this exemplary embodiment, if the first heat generating element 221, for example, among the plurality of heat generating elements 220 generates the highest temperature, the first heat generating element 221 is pressed by the protruding portion 243 as described above. Consequently, the distance between the first heat generating element 221 and the heat dissipater 240 becomes smaller than the distances from the other heat generating elements 220 to the heat dissipater 240. A first thermally-conductive member 251 that becomes thinner when pressed by the heat dissipater 240 is provided between the first heat generating element 221 and the heat dissipater 240. The first thermally-conductive member 251 may be a thermally-conductive gel sheet or high-performance heat-dissipating grease, for example. Consequently, the distance between the first heat generating element 221 and the heat dissipater 240 becomes close to “0”. In this way, the heat generating elements 220 and the heat dissipater 240 are brought into contact with each other with no air gap between them and the distances from the heat generating elements 220 to the heat dissipater 240 are minimized.

On the other hand, a second thermally-conductive member 252 that is thicker than the first thermally-conductive member 251 when pressed by the heat dissipater 240 is provided between a second heat generating element 222 and the heat dissipater 240. The second thermally-conductive member 252 may be heat-dissipating rubber or a gap filler for heat dissipation, for example.

In this way, thermally-conductive members 250 that have different minimum possible thicknesses are used in accordance with the distances from the heat generating elements 220 to the heat dissipater 240. Accordingly, in addition to the protruding portion 243 described previously, the thermally-conductive members 250 in this exemplary embodiment can make the distance from a heat generating element that generates high temperature to the heat dissipater smaller than the distances from the other heat generating elements to the heat dissipater, thereby enhancing the heat dissipation performance.

Further, the cooling structure 230 of this exemplary embodiment includes the first holding mechanism 260 as mentioned above. The first holding mechanism 260 holds the heat dissipater 240 with constant pressure being applied to the heat generating elements 220 by the heat dissipater 240 while thermally coupling the heat dissipater 240 to the plurality of heat generating elements 220.

The first holding mechanism 260 includes pins and helical compression springs, which are not depicted. Holes into which the pins are inserted are formed in predetermined positions at the edges of the heat dissipater 240. In the first holding mechanism 260, a helical compression spring is placed around the leg part of each pin and the pins are inserted into the holes formed in the heat dissipater 240 to fix the heat dissipater 240 to the substrate 210. This urges the heat dissipater 240 toward the heat generating elements 220. The heat generating elements 220 are thus constantly pressed by the heat dissipater 240. The first holding mechanism 260 enhances the degree of contact between the heat generating elements 220 and the heat dissipater 240.

The degrees of contact of the heat generating elements 220 with the heat dissipater 240 vary among the heat generating elements 220. This phenomenon can occur due to aging degradation of the substrate 210, thermally-conductive members 250 and other elements. The aging degradation thus may reduce the degrees of contact of the heat generating elements 220 with the heat dissipater 240.

To address this, the cooling structure 230 according to this exemplary embodiment uses the protruding portion 243 to preferentially press a heat generating element that generates high temperature and uses the first holding mechanism 260 to constantly press the heat dissipater 240 against the heat generating elements 220. Accordingly, the degree of contact with the first heat generating element 221 that generates high temperature can be constantly maintained. This can prevent overheating of the first heat generating element 221 that generates high temperature.

The cooling structure 230 according to this exemplary embodiment thus prevents a decrease in the degree of contact between the heat generating elements 220 and the heat dissipater 240 due to aging degradation or other factors and constantly maintains the degree of contact between the first heat generating element 221 that generates high temperature and the heat dissipater 240.

Similarly, the electronic device 200 according to this exemplary embodiment can constantly maintain the degree of contact between the first heat generating element 221 that generates high temperature and the heat dissipater 240, thereby preventing an increase in the temperature of the first heat generating element 221.

Note that one example of the electronic device 200 of this exemplary embodiment is a PCIE-compliant card. PCIE-compliant cards are generally available in sizes such as full-size, short-size, and low-profile. The full-size PCIE-compliant card is specified as a height of 107 mm and a length of 312 mm. The short-size PCIE-compliant card is specified as a height of 107 mm and a length of 173 mm. “PCIE” is an abbreviation of “Peripheral Component Interconnect Express”.

### Third Exemplary Embodiment

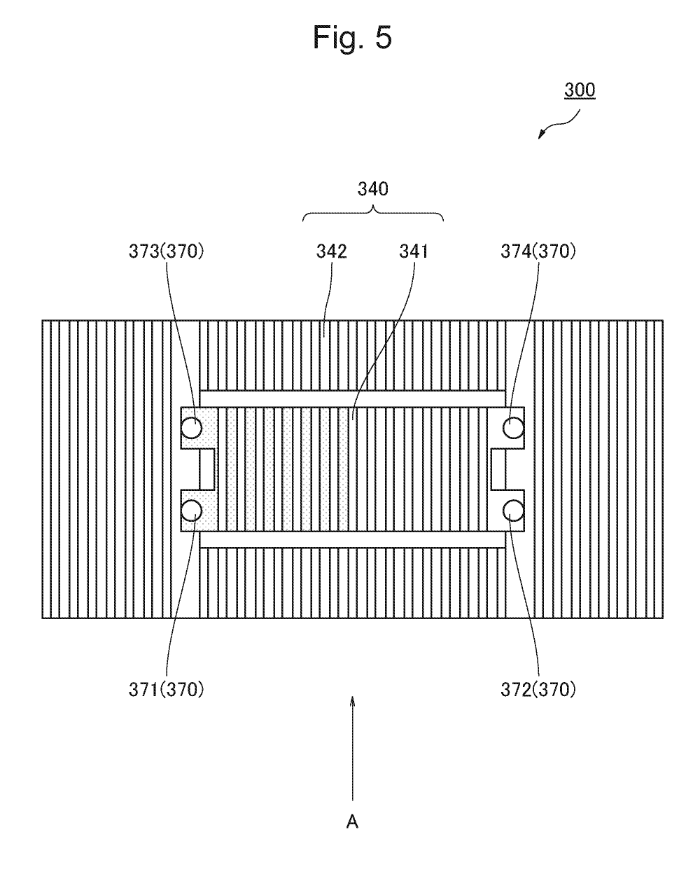

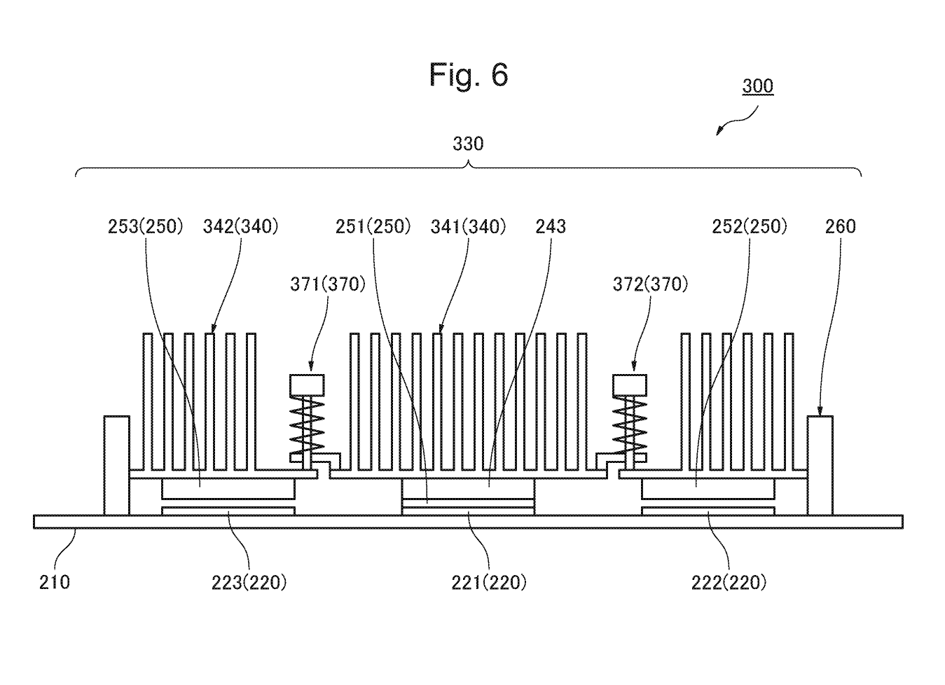

Another alternative exemplary embodiment (a third exemplary embodiment) of the present invention will be described with reference to FIGS. 5 and 6. FIG. 5 is a plan view illustrating a configuration of a cooling structure 330 according to this exemplary embodiment (the third exemplary embodiment) and an electronic device 300 equipped with the cooling structure 330. FIG. 6 is a side view illustrating the cooling structure and the electronic device viewed from direction A in FIG. 5.

The cooling structure 330 according to this exemplary embodiment differs from the cooling structure 230 according to the second exemplary embodiment described previously in that the cooling structure 330 includes a plurality of heat dissipaters 340 (a first heat dissipater 341 and a second heat dissipater 342). The cooling structure 330 according to this exemplary embodiment also differs in that the cooling structure 330 includes a second holding mechanism 370. The cooling structure 330 according to this exemplary embodiment is similar in other respects to the cooling structure 230 according to the second exemplary embodiment with the only differences mentioned above. Therefore, elements that are equivalent to elements of the second exemplary embodiment described previously are given the same or equivalent reference numerals and the description of those elements will be omitted.

The cooling structure 330 according to this exemplary embodiment includes a plurality of heat dissipaters 340 and the first heat dissipater 341 is provided for a heat generating element 221 that generates the highest temperature. In the cooling structure 330, the first heat dissipater 341 is coupled separately from the other heat dissipater(s) 340 (for example the second heat dissipater 342). The first heat dissipater 341 is coupled to the second heat dissipater 342 through the second holding mechanism 370.

Like the first holding mechanism 260, the second holding mechanism 370 includes pins and helical compression springs, which are not depicted. Holes into which the pins are inserted are formed at the four corners of the first heat dissipater 341. In the second holding mechanism 370, a helical compression spring is placed around the leg part of each pin and the pins are inserted into the holes. This constantly presses the first heat dissipater 341 against the second heat dissipater 342. In this way, the entire heat dissipater 340 can be prevented from tilting. If the size of the heat dissipater 340 is increased in order to increase the dissipation effect of the heat dissipater 340, a tilt of the heat dissipater 340 will result in a greater distance between an outer edge of the heat dissipater 340 and heat generating elements 220. To address this, the first heat dissipater 341 located in the center is separated in this exemplary embodiment, so that a tilt of the entire heat dissipater 340 can be reduced.

Note that in the first to third exemplary embodiments, the protruding potions 143, 243 may be integrally molded with the heat dissipaters 140, 240 and the first heat dissipater 341 or may be made as separate parts.

As described above, since the first heat dissipater 341 of the cooling structure 330 according to this exemplary embodiment is separated, a tilt of the entire heat dissipater 340 can be prevented or reduced even if the size of the heat dissipater 340 is increased. Thus, the cooling structure 330 according to this exemplary embodiment is capable of preventing unevenness of heat dissipation performance.

The previous description of embodiments is provided to enable a person skilled in the art to make and use the present invention. Moreover, various modifications to these exemplary embodiments will be readily apparent to those skilled in the art, and the generic principles and specific examples defined herein may be applied to other embodiments without the use of inventive faculty.

Therefore, the present invention is not intended to be limited to the exemplary embodiments described herein but is to be accorded the widest scope as defined by the limitations of the claims and equivalents. Further, it is noted that the inventor's intent is to retain all equivalents of the claimed invention even if the claims are amended during prosecution.

### REFERENCE SIGNS LIST

100 Electronic device
120 Heat generating element
130 Cooling structure
140 Heat dissipater

1. A cooling structure comprising:
a heat dissipater which is disposed in such a way as to thermally couple to a plurality of heat generating elements and dissipates heat generated by the plurality of heat generating elements; and
a protruding portion which is positioned at a surface of the heat dissipater, the surface facing the plurality of heat generating elements, and reduces a distance to the heat generating element.

2. The cooling structure according to claim 1, the heat generating element is the one that generates the highest temperature among the plurality of heat generating elements.

3. The cooling structure according to claim 1, further comprising a first holding mechanism which holds the heat dissipater with constant pressure being applied to the heat generating elements by the heat dissipater while thermally coupling the heat dissipater to the plurality of heat generating elements.

4. The cooling structure according to claim 1, further comprising a plurality of thermally-conductive members each of which is interposed between each of the plurality of heat generating elements and the heat dissipater and transfers heat generated by the plurality of heat generating elements into the heat dissipater,
wherein the plurality of thermally-conductive members are made of materials that have different minimum possible thicknesses in accordance with distances from the plurality of heat generating elements to the heat dissipater.

5. The cooling structure according to claim 1,
wherein a thermally-conductive member among the plurality of thermally-conductive members that is interposed between the heat dissipater and a heat generating element at a smaller distance to the heat dissipater among the plurality of heat generating elements is made of a material having a smaller minimum possible thickness than a material of a thermally-conductive member interposed between the heat dissipater and a heat generating element at a greater distance to the heat dissipater.

6. The cooling structure according to claim 1, comprising a plurality of heat dissipaters, wherein a first heat dissipater out of the plurality of heat dissipaters is disposed in a position corresponding to a heat generating element that generates a highest temperature among the plurality of heat generating elements and the first heat dissipater is formed separately from another heat dissipater disposed in a position corresponding to another heat generating element.

7. The cooling structure according to claim 6,
wherein the first heat dissipater is coupled to the another heat dissipater through a second holding mechanism.

8. The cooling structure according to claim 1, wherein the protruding portion is integrally molded with the heat dissipater.

9. The cooling structure according to claim 1, wherein the protruding portion and the heat dissipater are made as separate parts.

10. A heat dissipater comprising a protruding portion which is positioned at a surface facing heat generating elements and reduces a distance to the heat generating element.

11. A device comprising:
a plurality of heat generating elements; and
a cooling structure, the cooling structure comprising:
a heat dissipater which is disposed in such a way as to thermally couple to the plurality of heat generating elements and dissipates heat generated by the plurality of heat generating elements; and
a protruding portion which is positioned at a surface of the heat dissipater, the surface facing the heat generating elements, and reduces a distance to the heat generating element.
